(19) United States
(12) Patent Application Publication
(10) Pub. No.: US 2026/0057954 A1
(43) Pub. Date: Feb. 26, 2026

(54) MEMORY DEVICE ADOPTING ON-CHIP ECC SCHEME AND TEST METHOD THEREOF

(71) Applicant: SK hynix Inc., Gyeonggi-do (KR)

(72) Inventor: Jun Hyun SONG, Gyeonggi-do (KR)

(21) Appl. No.: 19/001,591

(22) Filed: Dec. 26, 2024

(30) Foreign Application Priority Data
Aug. 20, 2024 (KR) 10-2024-0111157

(51) Int. Cl. G11C 29/42; G11C 29/12; G11C 29/44

(52) U.S. Cl. CPC G11C 29/42; G11C 29/1201; G11C 29/44

(57) ABSTRACT

A memory device includes a normal cell region and a parity cell region; an error correction circuit configured to perform an error correction operation on read data output from the normal cell region based on read parity bits output from the parity cell region to generate error-corrected data; a miscorrection detection circuit configured to detect whether the error correction operation is performed on the read data not containing an error bit to generate a miscorrection detection signal; and a test output circuit configured to generate, in a test mode, a test result signal corresponding to the error-corrected data while masking the test result signal according to the miscorrection detection signal.

### CROSS-REFERENCE TO RELATED APPLICATION

The present application claims the benefit of Korean Patent Application No. 10-2024-0111157, filed on Aug. 20, 2024, which is incorporated herein by reference in its entirety.

### BACKGROUND

### 1. Field

Various embodiments of the present disclosure relate to a semiconductor design technology, and more particularly, to a test method of a memory device employing an on-chip ECC scheme.

### 2. Description of the Related Art

In the early days of the semiconductor memory industry, there were many original good dies with no defective memory cells, in a memory chip that has passed a semiconductor fabrication process on the wafer. However, as the capacity of memory devices gradually increased, it became difficult to make a memory device completely free of a defective memory cell, and at present, it may be said that there is likely no possibility that a memory device with no defective memory cell is fabricated. As one solution to overcome this situation, a method of repairing defective memory cells of a memory device with redundant memory cells or a method of correcting an error in data of memory cells using an error correction circuit is being used.

In the case of a memory device employing an on-chip ECC scheme, a method for allocating and storing parity bits for ECC to a partial memory region (hereinafter, referred to as a “parity cell region”) of a memory cell array has been proposed. Recently, various methods for efficiently testing a normal cell region and a parity cell region of a memory device employing an on-chip ECC scheme have been studied.

### SUMMARY

Embodiments of the present disclosure are directed to a test method of a memory device employing an on-chip ECC scheme.

In accordance with an embodiment of the present disclosure, a memory device includes a normal cell region and a parity cell region; an error correction circuit configured to perform an error correction operation on read data output from the normal cell region based on read parity bits output from the parity cell region to generate error-corrected data; a miscorrection detection circuit configured to detect whether the error correction operation is performed on the read data not containing an error bit to generate a miscorrection detection signal; and a test output circuit configured to generate, in a test mode, a test result signal corresponding to the error-corrected data while masking the test result signal according to the miscorrection detection signal.

In accordance with an embodiment of the present disclosure, a memory device includes an error correction circuit configured to generate an error location signal indicating a location of an error bit of read data based on read parity bits, and perform an error correction operation on the read data according to the error location signal to generate error-corrected data; a miscorrection detection circuit configured to detect whether the error correction operation is performed on the read data not containing an error bit, according to the read data and the error location signal to generate a miscorrection detection signal; and a test output circuit configured to generate, in a test mode, a test result signal corresponding to the error-corrected data while masking the test result signal according to the miscorrection detection signal.

In accordance with an embodiment of the present disclosure, a test method of a memory device includes generating an error location signal indicating a location of an error bit of read data based on read parity bits; performing an error correction operation on the read data according to the error location signal to generate error-corrected data; detecting whether the error correction operation is performed on the read data not containing an error bit, according to the read data and the error location signal to generate a miscorrection detection signal; and generating a test result signal corresponding to the error-corrected data while masking the test result signal according to the miscorrection detection signal.

According to embodiments of the present disclosure, the memory device can prevent a false fail determination for normal cells caused by a miscorrection of an on-chip ECC circuit during a test operation. Therefore, it is possible to increase the yield by preventing an unnecessary repair operation.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory device according to an embodiment of the present disclosure.

FIG. 2 is a detailed configuration diagram illustrating a memory cell region of FIG. 1.

FIG. 3 is a diagram for describing a miscorrection of an error correction circuit due to a fault of a sub-word line driver.

FIG. 4 is a detailed configuration diagram illustrating an error correction circuit of FIG. 1.

FIG. 5 is a circuit diagram illustrating an error corrector of FIG. 4.

FIG. 6 is a circuit diagram illustrating a miscorrection detection circuit of FIG. 1.

FIG. 7 is a circuit diagram illustrating a test output circuit of FIG. 1.

FIG. 8 is a table for describing states of signals for each case according to an embodiment of the present disclosure.

FIGS. 9A to 9D are diagrams for describing a test operation for each case according to an embodiment of the present disclosure.

FIG. 10 is a flowchart for describing a test operation of a memory device according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit or element intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

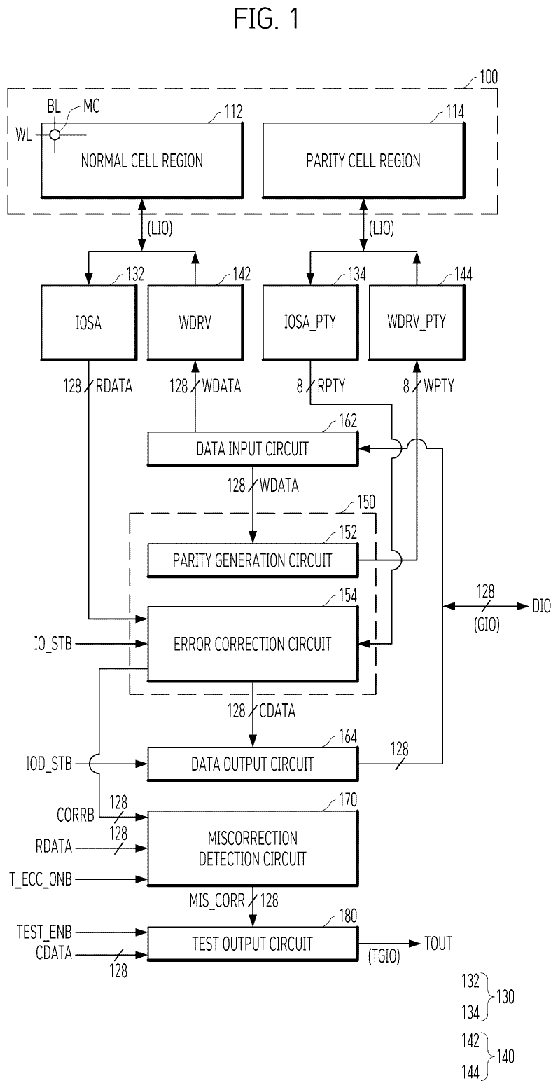

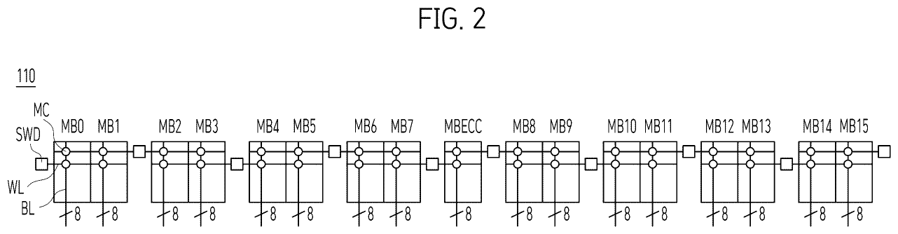

FIG. 1 is a block diagram illustrating a memory device 100 according to an embodiment of the present disclosure. FIG. 2 is a detailed configuration diagram illustrating a memory cell region 110 of FIG. 1.

Referring to FIG. 1, the memory device 100 may include the memory cell region 110, a read circuit 130, a write circuit 140, an error correction code (ECC) engine 150, a data input circuit 162, a data output circuit 164, a miscorrection detection circuit 170, and a test output circuit 180.

The memory cell region 110 may include a normal cell region 112 for storing normal data (or user data) and a parity cell region 114 for storing parity bits for correcting an error in the normal data. The parity bits may be referred to as an error correction code. In the normal cell region 112 and the parity cell region 114, a plurality of cell blocks which are arranged in an array form in a row direction and a column direction may be arranged. Each cell block may include a plurality of memory cells MC coupled between a plurality of word lines WL and a plurality of bit lines BL. In an embodiment of the present disclosure, a “cell block” may be defined as a set of memory cells which share the word lines WL and the bit lines BL and are arranged in the same form. Although not shown, a plurality of sub-word line drivers may be arranged between cell blocks which are arranged in the row direction, and a plurality of bit line sense amplifiers may be arranged between cell blocks which are arranged in the column direction.

Referring to FIG. 2, a plurality of cell blocks arranged in a row direction are shown. A plurality of cell blocks (for example, normal cell blocks MB0 to MB15) may be disposed in the normal cell region 112, and at least one cell block (for example, a parity cell block MBECC) may be disposed in the parity cell region 114. Each of the cell blocks MB0 to MB15 and MBECC may include a plurality of memory cells MC coupled between a plurality of word lines WL and a plurality of bit lines BL.

Each of the cell blocks MB0 to MB15 and MBECC may alternately share the sub-word line drivers SWD with adjacent cell blocks. Rectangles between the cell blocks MB0 to MB15, and MBECC may represent sub-word line drivers SWD, and lines extending left and right of the sub-word line drivers SWD may represent word lines (or sub-word lines, WL). One sub-word line driver SWD may be allocated up to four cell blocks in the row direction. In reality, there are far more sub-word line drivers and word lines, but only a few are shown here to represent a simple structure.

During a read operation or write operation, each of the cell blocks MB0 to MB15 and MBECC may input or output data in a predetermined bit unit. In the following description, a case where each of the cell blocks MB0 to MB15 and MBECC inputs or outputs data in an 8-bit unit during a write operation or read operation will be described as an example. Each of the cell blocks MB0 to MB15 and MBECC may read 8-bit data from memory cells, or write 8-bit data to the memory cells coupled between a word line designated by a row address and a predetermined number (e.g., 8) bit lines designated by a column address. Accordingly, the memory device 100 may input or output 128-bit data during a single write operation or read operation and use an 8-bit error correction code. For reference, all sub-word line drivers SWD located at a same level in the row direction may be activated to select the word line designated by the row address.

Referring back to FIG. 1, the read circuit 130 may include a normal read circuit (IOSA) 132 and a parity read circuit (IOSA_PTY) 134. The normal read circuit 132 may sense and amplify data output from the normal cell region 112 and output the sensed and amplified data as 128-bit read data RDATA, during a read operation. The parity read circuit 134 may sense and amplify data output from the parity cell region 114 and output the sensed and amplified data as 8-bit read parity bits RPTY, during the read operation. The normal read circuit 132 and the parity read circuit 134 may be implemented with I/O sense amplifiers.

The write circuit 140 may include a normal write circuit (WDRV) 142 and a parity write circuit (WDRV_PTY) 144. The normal write circuit 142 may write 128-bit write data WDATA transmitted from the data input circuit 162 to the normal cell region 112, during a write operation. The parity write circuit 144 may write 8-bit write parity bits WPTY transmitted from the ECC engine 150 to the parity cell region 114, during the write operation. The normal write circuit 142 and the parity write circuit 144 may be implemented with write drivers.

Depending on an embodiment, in a test mode, the normal write circuit 142 and the parity write circuit 144 may set the write data WDATA and the write parity bits WPTY to a preset target test pattern to write the preset target test pattern to the normal cell region 112 and the parity cell region 114. The normal read circuit 132 and the normal write circuit 142 may input/output data to/from the normal cell region 112 through a local input/output line LIO, and the parity read circuit 134 and the parity write circuit 144 may input/output data to/from the parity cell region 114 through the local input/output line LIO.

The ECC engine 150 may include a parity generation circuit 152 and an error correction circuit 154. The ECC engine 150 may also be referred to as an on-chip ECC engine.

The parity generation circuit 152 may calculate write parity bits WPTY using the write data WDATA transmitted from the data input circuit 162. The write parity bits WPTY may be data for correcting an error in the write data WDATA. The parity generation circuit 152 may generate the 8-bit write parity bits WPTY using the 128-bit write data WDATA.

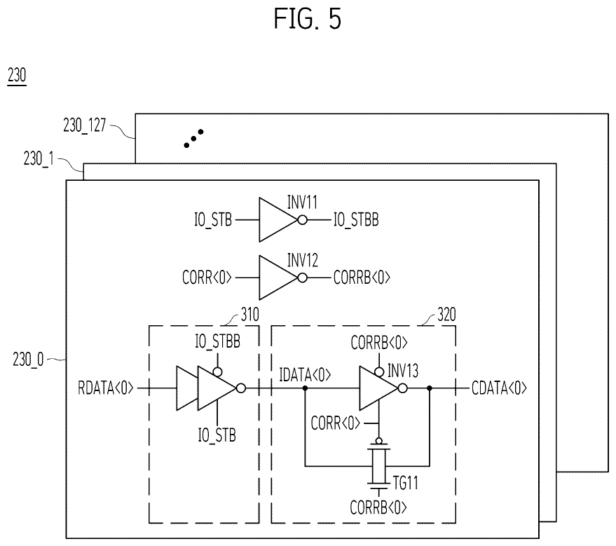

The error correction circuit 154 may output error-corrected data CDATA by performing an error correction operation on the read data RDATA using the read parity bits RPTY. The error correction circuit 154 may generate an error location signal (CORR of FIG. 5) indicating a location of a bit (hereinafter, referred to as an “error bit”) in which an error is located among bits (hereinafter, referred to as “read bits”) of the read data RDATA based on the read parity bits RPTY. The error correction circuit 154 may perform an error correction operation of inverting the error bit of the read data RDATA according to the error location signal CORR. The error correction circuit 154 may output an inverted error location signal CORRB which is generated by inverting the error location signal CORR, to the miscorrection detection circuit 170. Each of the error location signal CORR and the inverted error location signal CORRB may be composed of bits corresponding to the number of bits (i.e., 128-bits) of the read data RDATA. When error bits beyond an error correction capability occur, the error correction circuit 154 may generate an error location signal CORR for normal bits, not the error bits.

The data input circuit 162 may receive the write data WDATA by buffering external data DIO input to a global input/output line GIO through a data pad (not shown). The data input circuit 162 may transmit the write data WDATA to the normal write circuit 142 and the parity generation circuit 152, respectively.

The data output circuit 164 may receive the error-corrected data CDATA transmitted from the error correction circuit 154 to output the external data DIO to the global input/output line GIO. For reference, the error correction circuit 154 and the data output circuit 164 may operate according to strobe signals having a delay time preset for a timing margin. For example, the error correction circuit 154 may operate in synchronization with a first strobe signal IO_STB, and the data output circuit 164 may operate in synchronization with a second strobe signal IOD_STB which is generated by delaying the first strobe signal IO_STB. The data output circuit 164 may be implemented with drivers (or inverters) for receiving the read data RDATA to output the external data DIO to the global input/output line GIO in synchronization with the second strobe signal IOD_STB. Although not shown, a normal mode signal activated in a normal mode other than the test mode is provided to the data output circuit 164, and the data output circuit 164 may operate only in the normal mode.

The miscorrection detection circuit 170 may generate a miscorrection detection signal MIS_CORR according to the read data RDATA, the inverted error location signal CORRB, and an on-chip ECC mode signal T_ECC_ONB. The on-chip ECC mode signal T_ECC_ONB may be activated to a logic low level when the ECC engine 150 operates for an on-chip ECC scheme in the test mode. The miscorrection detection circuit 170 may be activated according to the on-chip ECC mode signal T_ECC_ONB, and determine whether the read data RDATA includes an error bit by checking whether the read data RDATA correspond to the target test pattern, and determine whether an error correction operation has been performed on the read data RDATA based on the inverted error location signal CORRB. Accordingly, the miscorrection detection circuit 170 may generate the miscorrection detection signal MIS_CORR by detecting a case in which the read data RDATA does not contain the error bit but the error correction operation has been performed on the read data RDATA (i.e., a case where the error correction operation has been performed on the read data not containing the error bit), in the test mode to which the on-chip ECC scheme is applied.

The test output circuit 180 may output a test result signal TOUT according to a test mode signal TEST_ENB, the miscorrection detection signal MIS_CORR, and the error-corrected data CDATA. The test mode signal TEST_ENB may be activated to a logic low level in the test mode. The test output circuit 180 may generate the test result signal TOUT corresponding to the error-corrected data CDATA in the test mode, while masking the test result signal TOUT according to the miscorrection detection signal MIS_CORR. The test output circuit 180 may output the test result signal TOUT indicating a pass/fail to a test input/output line TGIO. In an embodiment, the test mode may include a parallel test operation. However, the embodiments of the present disclosure are not limited thereto and may include various types of test operations.

Although not illustrated in FIG. 1, the data input circuit 162, the parity generation circuit 152, the normal write circuit 142, and the parity write circuit 144 may be activated during the write operation. For example, the data input circuit 162, the parity generation circuit 152, the normal write circuit 142, and the parity write circuit 144 may be activated according to a write command. On the other hand, the normal read circuit 132, the parity read circuit 134, the error correction circuit 154, the data output circuit 164, the miscorrection detection circuit 170, and the test output circuit 180 may be activated during the read operation. For example, the normal read circuit 132, the parity read circuit 134, the error correction circuit 154, the data output circuit 164, the miscorrection detection circuit 170, and the test output circuit 180 may be activated according to a read command.

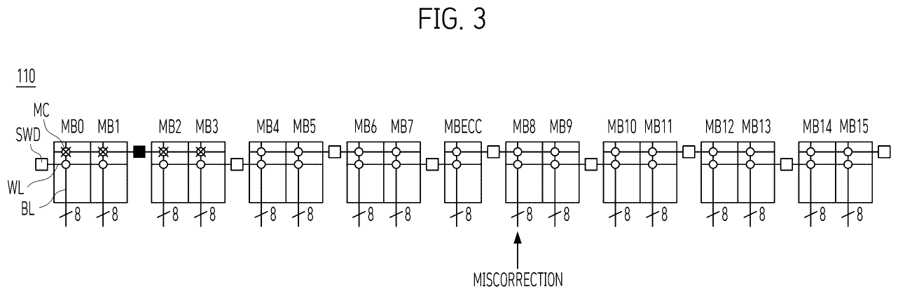

FIG. 3 is a diagram for describing a miscorrection of the error correction circuit 154 due to a fault of a sub-word line driver.

Referring to FIG. 3, since adjacent cell blocks of the cell blocks MB0 to MB15 and MBECC share sub-word line drivers, when a defect occurs in the sub-word line driver, there is a high possibility that an error may occur in cell blocks on both sides of the sub-word line driver. For example, since a second normal cell block MB1 and a third normal cell block MB2 share a sub-word line driver, when a defect occurs in the shared sub-word line driver, an error may occur simultaneously in the first to fourth normal cell blocks MB0 to MB3.

In this case, due to the occurrence of an error exceeding the error correction capability of the error correction circuit 154, a miscorrection of performing an error correction operation on data of a normal cell block in which an error has not occurred may occur. The number of error bits may be further increased in data output from the memory device 100 due to the miscorrection.

During a parallel test operation that compresses and outputs the error-corrected data CDATA, an incorrect test result signal TOUT may be generated due to the miscorrection, and the external test device (or memory controller) instructs a repair operation based on the incorrect test result signal TOUT. As a result, unnecessary repair operations are performed on normal cells, resulting in a decrease in redundancy efficiency.

In accordance with an embodiment of the present disclosure, the miscorrection detection circuit 170 may generate the miscorrection detection signal MIS_CORR by detecting a case in which the read data RDATA does not contain an error bit in the test mode but an error correction operation has been performed on the read data RDATA. The test output circuit 180 may generate the test result signal TOUT corresponding to the error-corrected data CDATA, while masking the test result signal TOUT according to the miscorrection detection signal MIS_CORR. Accordingly, the yield can be increased by preventing the case in which an incorrect test result signal TOUT is generated due to the miscorrection to prevent unnecessary repair operations.

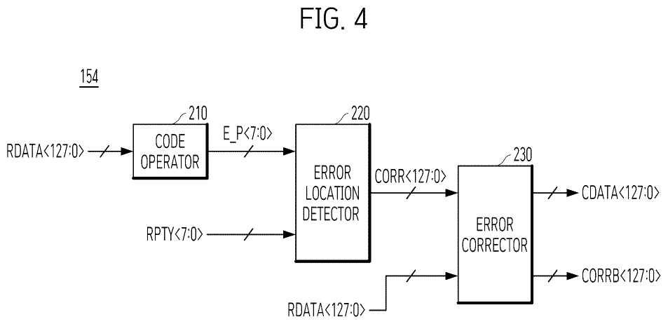

Hereinafter, a detailed configuration of each circuit of FIG. 1 will be described with reference to FIGS. 4 to 7.

FIG. 4 is a detailed configuration diagram illustrating the error correction circuit 154 of FIG. 1.

Referring to FIG. 4, the error correction circuit 154 may include a code operator 210, an error location detector 220, and an error corrector 230.

The code operator 210 may generate 8-bit preliminary parity bits E_P<7:0> using the 128-bit read data RDATA<127:0>. The preliminary parity bits E_P<7:0> may also be referred to as a preliminary error correction code. For example, the code operator 210 may generate the preliminary parity bits E_P<7:0> using a check matrix also called a H matrix. However, the embodiments of the present disclosure are not limited thereto, and the code operator 210 may generate an error correction code by applying a known BCH code, Hamming code, RS code, or the like, or may generate an error correction code by applying another type of parity code.

For reference, the parity generation circuit 152 of FIG. 1 may be implemented with substantially the same configuration as the code operator 210 included in the error correction circuit 154 of FIG. 4. According to an embodiment, the parity generation circuit 152 and the code operator of the error correction circuit 154 may be merged into a single configuration. That is, the parity generation circuit 152 may be used for a write operation, and the code operator of the error correction circuit 154 may be used for a read operation.

The error location detector 220 may compare the preliminary parity bits E_P<7:0> with the read parity bits RPTY<7:0> to generate the 128-bit error location signal CORR<127:0>. The error location detector 220 may compare the preliminary parity bits E_P<7:0> with the read parity bits RPTY<7:0> for each bit to generate an 8-bit syndrome, which is information obtained by encoding error location information, and decode the syndrome to generate the 128-bit error location signal CORR<127:0>. Bits (hereinafter, referred to as “error location bits”) of the 128-bit error location signal CORR<127:0> correspond to the read bits of the 128-bit read data RDATA<127:0>, and an error location bit corresponding to an error bit among read bits may be set to a high bit. For example, if the syndrome is (0, 1, 0, 0, 0, 0, 1), the error location detector 220 may set an 81-th error location bit CORR<80> corresponding to an 81-th read bit RDATA<80> to a high bit. That is, the error location signal CORR<127:0> may be a signal identifying an error bit of the read data RDATA<127:0>.

The error corrector 230 may generate the error-corrected data CDATA<127:0> by correcting an error in the read data RDATA<127:0> according to the error location signal CORR<127:0>. The error corrector 230 may perform an error correction operation of inverting the error bit of the read data RDATA<127:0> according to the error location signal CORR<127:0>. In addition, the error corrector 230 may output the 128-bit inverted error location signal CORRB<127:0> by inverting the error location signal CORR<127:0>.

When the error correction circuit 154 has the error correction capability for correcting 1-bit error, when an error bit occurs within the error correction capability (i.e., when a 1-bit error occurs), the error location detector 220 may set an error location bit corresponding to the error bit among the read bits, to a high bit. However, when error bits beyond the error correction capability occur, i.e., when a multi-bit error occurs, the error location detector 220 may not set an error location bit corresponding to the error bits among the read bits to a high bit, but may perform a malfunction of setting the error location bit corresponding to a normal read bit to a high bit. Due to this malfunction, the error corrector 230 performs an error correction operation of inverting the normal read bit. As a result, when the error bits beyond the error correction capability occur, the miscorrection of the error correction circuit 154 occurs.

FIG. 5 is a circuit diagram illustrating the error corrector 230 of FIG. 4.

Referring to FIG. 5, the error corrector 230 may include first to 128-th error correction parts 230_0 to 230_127 corresponding to each bit of the read data RDATA<127:0>.

Each of the first to 128-th error correction parts 230_0 to 230_127 may receive a corresponding read bit in synchronization with the first strobe signal IO_STB, selectively invert the received read bit in response to a corresponding error location bit, and output the received read bit as a corresponding bit (hereinafter, referred to as an “error-corrected bit”), among bits of the error-corrected data CDATA<127:0>. Hereinafter, since the first to 128-th error correction parts 230_0 to 230_127 have substantially the same configuration, the first error correction part 230_0 will be described as an example.

The first error correction part 230_0 may include an input unit 310 and a selective inversion unit 320. In addition, the first error correction part 230_0 may include a first inverter INV11 for inverting the first strobe signal IO_STB to generate a first inverted strobe signal IO_STBB and a second inverter INV12 for inverting a first error location bit CORR<0> to generate a first inverted error location bit CORRB<0>. In FIG. 5, the first inverter INV11 and the second inverter INV12 are shown to be included in the first error correction part 230_0, but the embodiment is not limited thereto, and the first inverter INV11 and/or the second inverter INV12 may be disposed outside the first error correction part 230_0 and may be shared by other error correction parts.

The input unit 310 may receive a first read bit RDATA<0> in synchronization with the first strobe signal IO_STB and the first inverted strobe signal IO_STBB, to output an internal data bit IDATA<0>. The input unit 310 may include an even number of inverters that buffer the first read bit RDATA<0> according to the first strobe signal IO_STB and the first inverted strobe signal IO_STBB to output the internal data bit IDATA<0>.

The selective inversion unit 320 may selectively invert the internal data bit IDATA<0> according to the first error location bit CORR<0> and the first inverted error location bit CORRB<0>, to output the first error-corrected bit CDATA<0>. For example, when the first error location bit CORR<0> becomes a high bit, the selective inversion unit 320 may invert the internal data bit IDATA<0> to output the first error-corrected bit CDATA<0>, and when the first inverted error location bit CORRB<0> becomes a high bit, the selective inversion unit 320 may output the internal data bit IDATA<0> as the first error-corrected bit CDATA<0>.

In detail, the selective inversion unit 320 may include a third inverter INV13 and a transfer gate TG11.

The third inverter INV13 may output the first error-corrected bit CDATA<0> by inverting the internal data bit IDATA<0>, in response to the first error location bit CORR<0> of a logic high level (i.e., the high bit) and the first inverted error location bit CORRB<0> of a logic low level (i.e., the low bit). The transfer gate TG11 may output the internal data bit IDATA<0> as the first error-corrected bit CDATA<0>, in response to the first inverted error location bit CORRB<0> of a logic high level and the first error location bit CORR<0> of a logic low level.

With the above configuration, one of the first to 128-th error correction parts 230_0 to 230_127 is selected by the error location signal CORR<127:0>, and a read bit input to the selected error correction part may be inverted (i.e., error correction) to be output as an error-corrected bit.

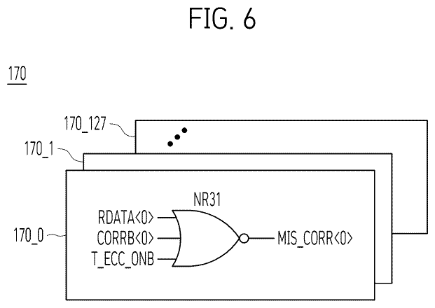

FIG. 6 is a circuit diagram illustrating the miscorrection detection circuit 170 of FIG. 1.

Referring to FIG. 6, the miscorrection detection circuit 170 may include first to 128-th detection parts (i.e., detection logics) 170_0 to 170_127 corresponding to each read bit of the read data RDATA<127:0>.

The first to 128-th detection parts 170_0 to 170_127 may be activated according to the on-chip ECC mode signal T_ECC_ONB, respectively. Each of the first to 128-th detection parts 170_0 to 170_127 may output a corresponding bit, among bit (hereinafter, referred to as “miscorrection detection bits”) of the miscorrection detection signal MIS_CORR, to a high bit, when a corresponding read bit is a target bit and a corresponding error location bit is a high bit. The target bit may be a bit corresponding to a read bit in the target test pattern. For example, when the target test pattern is composed of all-zero bits, the target bit may be set to a low bit. Hereinafter, since the first to 128-th detection parts 170_0 to 170_127 have substantially the same configuration, the first detection part 170_0 will be described as an example.

The first detection part 170_0 may include a NOR gate NR31 for outputting a first miscorrection detection bit MIS_CORR<0> by performing a logic NOR operation on the first read bit RDATA<0>, the first inverted error location bit CORRB<0>, and the on-chip ECC mode signal T_ECC_ONB. The first detection part 170_0 may output the first miscorrection detection bit MIS_CORR<0> of a logic low level when any one of the first read bit RDATA<0>, the first inverted error location bit CORRB<0>, and the on-chip ECC mode signal T_ECC_ONB has a logic high level. Further, the first detection part 170_0 may output the first miscorrection detection bit MIS_CORR<0> of a logic high level when all of the first read bit RDATA<0>, the first inverted error location bit CORRB<0>, and the on-chip ECC mode signal T_ECC_ONB are at a logic low level.

In this case, the first inverted error location bit CORRB<0> may be activated to a logic low level when the first read bit RDATA<0> is detected as an error bit so that an error correction operation is performed on the first read bit RDATA<0>. The on-chip ECC mode signal T_ECC_ONB may be activated to a logic low level when the ECC engine 150 operates for an on-chip ECC scheme in the test mode. Accordingly, the first detection part 170_0 is activated in the test mode to which the on-chip ECC scheme is applied, and output the first miscorrection detection bit MIS_CORR<0> of a logic high level when the first read bit RDATA<0> is at a logic low level (i.e., the target bit) and an error correction operation is performed on the first read bit RDATA<0>.

With the above configuration, the first to 128-th detection parts 170_0 to 170_127 may detect a case in which the corresponding read bit of the read data RDATA is not an error bit but an error correction operation has been performed in the test mode to which the on-chip ECC scheme is applied, respectively, to generate a corresponding miscorrection detection bit of the miscorrection detection signal MIS_CORR.

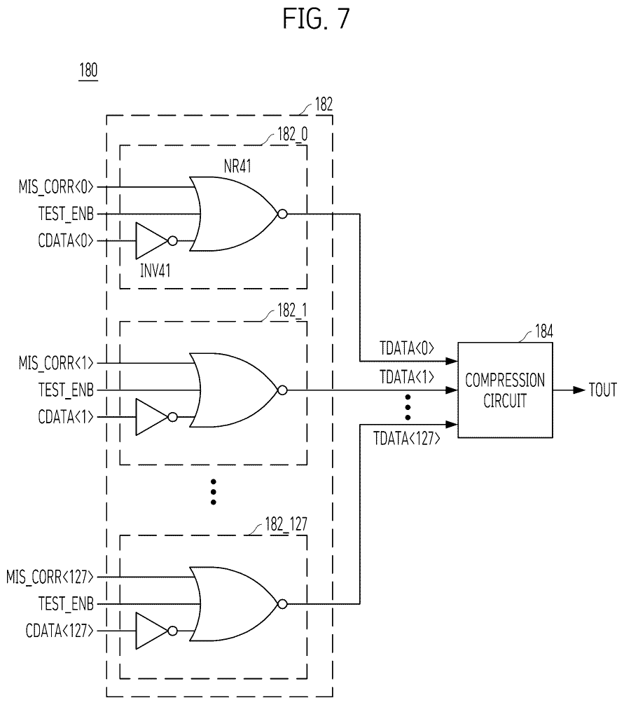

FIG. 7 is a circuit diagram illustrating the test output circuit 180 of FIG. 1.

Referring to FIG. 7, the test output circuit 180 may include a masking circuit 182 and a compression circuit 184.

The masking circuit 182 may generate 128-bit test data TDATA<127:0> by selectively masking the 128-bit error-corrected data CDATA<127:0> according to the 128-bit miscorrection detection signal MIS_CORR<127:0> in the test mode.

In detail, the masking circuit 182 may include first to 128-th masking parts (i.e., masking logics) 182_0 to 182_127 corresponding to the error-corrected bits, respectively.

The first to 128-th masking parts 182_0 to 182_127 may be activated according to a test mode signal TEST_ENB. Each of the first to 128-th masking parts 182_0 to 182_127 may output a corresponding bit among bits (hereinafter, referred to as “test bits”) of the test data TDATA<127:0>, by selectively masking a corresponding error-corrected bit according to a corresponding miscorrection detection bit. Hereinafter, since the first to 128-th masking parts 182_0 to 182_127 have substantially the same configuration, the first masking part 182_0 will be described as an example.

The first masking part 182_0 may include an inverter INV41 and a NOR gate NR41. The inverter INV41 may invert the first error-corrected bit CDATA<0>. The NOR gate NR41 may output a first test bit TDATA<0> by performing a logic NOR operation on an output of the inverter INV41, the first miscorrection detection bit MIS_CORR<0>, and the test mode signal TEST_ENB. The first masking part 182_0 may output the first error-corrected bit CDATA<0> as a first test bit TDATA<0> when both the first miscorrection detection bit MIS_CORR<0> and the test mode signal TEST_ENB are at a logic low level. On the other hand, the first masking part 182_0 may fix and output the first test bit TDATA<0> at a logic low level when one of the first miscorrection detection bit MIS_CORR<0> and the test mode signal TEST_ENB is at a logic high level.

With the above configuration, each of the first to 128-th masking parts 182_0 to 182_127 may be activated in a test mode, and when the corresponding miscorrection detection bit is at a logic high level, set a corresponding test bit to a target bit (i.e., a logic low level) regardless of a logic level of the corresponding error-corrected bit.

The compression circuit 184 may compress the 128-bit test data TDATA<127:0> to output a 1-bit test result signal TOUT. The compression circuit 184 may output the test result signal TOUT indicating that the test result is a pass to the test input/output line TGIO when all of the test bits of the test data TDATA<127:0> are at a logic low level. For reference, in the test mode, when no error is detected or the detected error is corrected, the test result may be determined as a pass. The compression circuit 184 may output the test result signal TOUT indicating that the test result is a fail to the test input/output line TGIO when any of the test bits is at a logic high level. For example, when the test result is a pass, the test result signal TOUT may be at a logic high level, and when the test result is a fail, the test result signal TOUT may be at a logic low level. Compression circuit 184 may be implemented with logic gates performing an exclusive OR (XOR) operation or an exclusive NOR (XNOR) operation to compare test bits with each other.

According to an embodiment, the compression circuit 184 may compress the 128-bit test data TDATA<127:0> into a predetermined bit unit (e.g., 32 bits) to output a test result signal TOUT. For example, the compression circuit 184 may output the test result signal TOUT by compressing test bits corresponding to data output from the first to fourth normal cell blocks MB0 to MB3 of FIG. 2, output test result signal TOUT by compressing test bits corresponding to data output from the fifth to eighth normal cell blocks MB4 to MB7 of FIG. 2, and in this way, output test result signal TOUT by compressing test bits corresponding to data output from the 13-th to 16-th normal cell blocks MB12 to MB15. That is, the compression circuit 184 may group cell blocks in a predetermined number and output a test result signal TOUT corresponding each test result of the grouped cell blocks. The compression circuit 184 may output each test result as a 4-bit test result signal TOUT at once, or sequentially output each test result as a 1-bit test result signal TOUT.

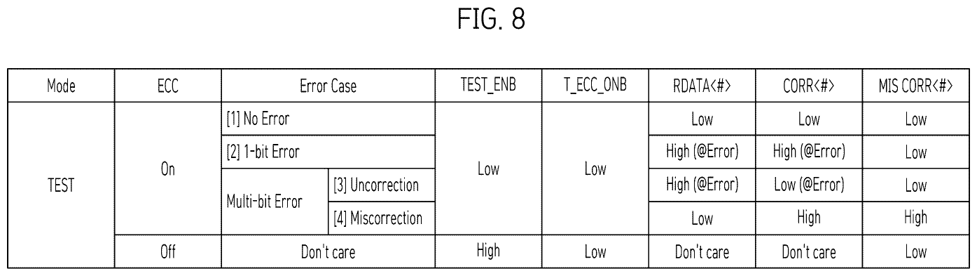

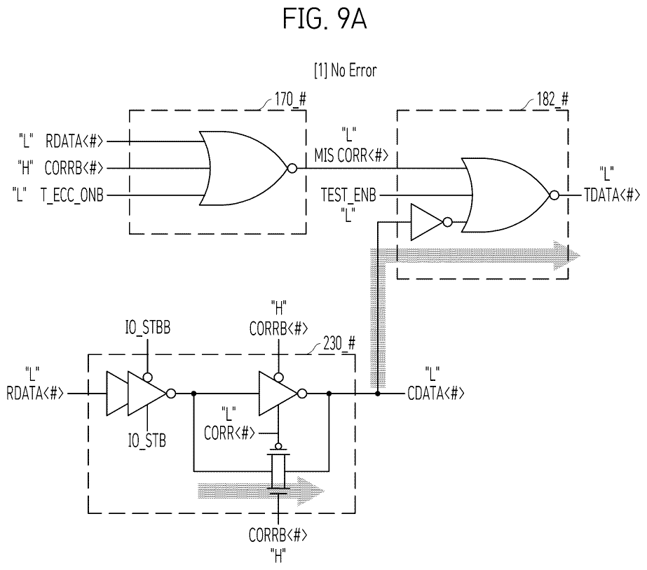

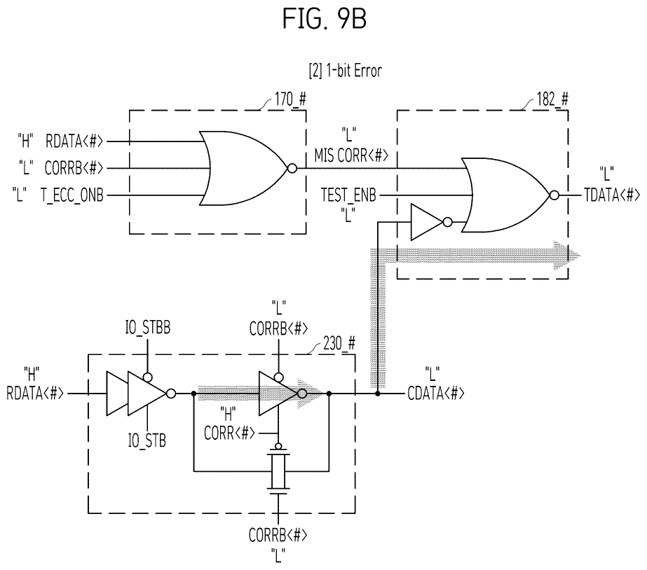

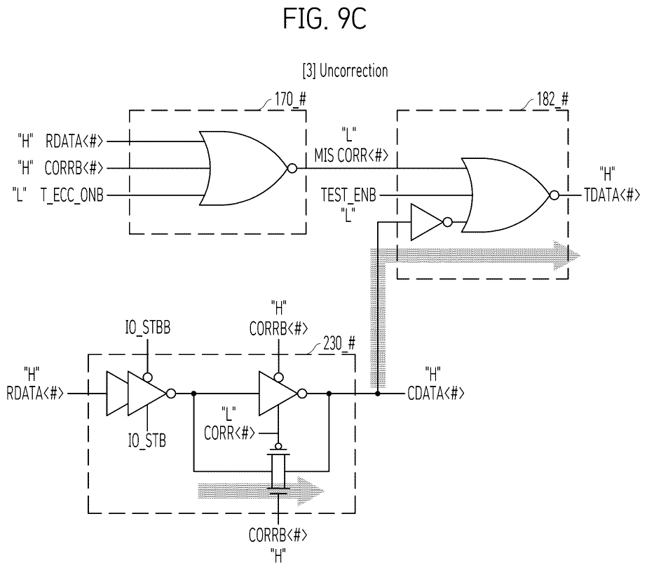

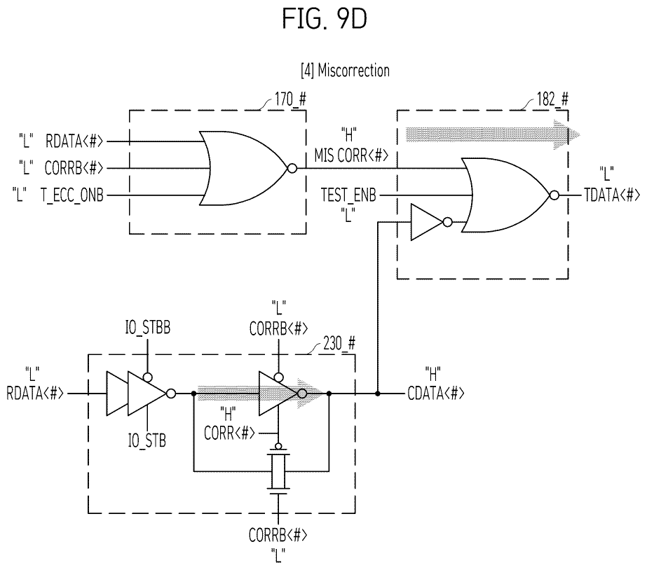

Hereinafter, an operation for each case according to an embodiment of the present disclosure will be described with reference to FIGS. 8 to 9D.

FIG. 8 is a table for describing states of signals for each case according to an embodiment of the present disclosure. FIGS. 9A to 9D are diagrams for describing a test operation for each case according to an embodiment of the present disclosure.

Referring to FIG. 8, logic levels of the signals of FIG. 1 when the on-chip ECC scheme in the test mode and the normal mode is applied or not will be described. In the table, the reference numeral “#” may specify a bit of corresponding data. For example, #may include an integer from 0 to 127.

When the on-chip ECC scheme is applied in the test mode, there may be four types of error cases. The first error case “[1] No Error” is a case in which an error has not occurred in a read bit RDATA<#>, and the second error case “(2) 1-bit Error” is a case in which an error has occurred in a read bit RDATA<#> but the error has been corrected. The third error case “[3] Uncorrection” and the fourth error case “[4] Miscorrection” are cases in which a multi-bit error of 2 or more bits exceeds the error correction capability of the error correction circuit 154 occurs. The third error case “[3] Uncorrection” is a case in which an error has occurred in a read bit RDATA<#> in a situation in which a multi-bit error has occurred but the error has not been corrected, and the fourth error case “[4] Miscorrection” is a case in which a miscorrection has occurred since no error has occurred in a read bit RDATA<#> but the read bit RDATA<#> has been corrected. In the first to fourth error cases, both the test mode signal TEST_ENB and the on-chip ECC mode signal T_ECC_ONB may be activated to a logic low level.

First, in the first error case, the read bit RDATA<#> is a logic low level which is a target bit. Since no error has occurred, the error location detector 220 generates an error location bit CORR<#>corresponding to the read bit RDATA<#> at a logic low level, and accordingly, an inverted error location bit CORRB<#> may be output at a logic high level.

Referring to FIG. 9A, the error correction part 230_# of the error corrector 230 may output the read bit RDATA<#> as an error-corrected bit CDATA<#> according to the error location bit CORR<#> of a logic low level. The detection part 170_# of the miscorrection detection circuit 170 may output a miscorrection detection bit MIS_CORR<#> of a logic low level, when any of the read bit RDATA<#>, the inverted error location bit CORRB<#> and the on-chip ECC mode signal T_ECC_ONB has a logic high level. That is, the detection part 170_# may output the miscorrection detection bit MIS_CORR<#> of a logic low level according to the inverted error location bit CORRB<#> of a logic high level. The masking part 182_# of the masking circuit 182 may generate a test bit TDATA<#> by selectively masking the error-corrected bit CDATA<#> according to the miscorrection detection bit MIS_CORR<#>. In this case, the masking part 182_# may output the error-corrected bit CDATA<#> of a logic low level as the test bit TDATA<#> according to the miscorrection detection bit MIS_CORR<#> of a logic low level.

Next, in the second error case, a read bit RDATA<#> which is an error bit, becomes a logic high level. The error location detector 220 generates an error location bit CORR<#> corresponding to the read bit RDATA<#> at a logic high level, and accordingly, an inverted error location bit CORRB<#> may be output at a logic low level.

Referring to FIG. 9B, the error correction part 230_# may invert the read bit RDATA<#> according to the error location bit CORR<#> of a logic high level to output an error-corrected bit CDATA<#> of a logic low level. The detection part 170_# may output a miscorrection detection bit MIS_CORR<#> of a logic low level according to the read bit RDATA<#> of a logic high level. The masking part 182_# may output the error-corrected bit CDATA<#> of a logic low level as a test bit TDATA<#> according to the miscorrection detection bit MIS_CORR<#> of a logic low level.

Next, in the third error case, a read bit RDATA<#> becomes a logic high level as one error bit among error bits. When a multi-bit error occurs, since the number of error bits beyond the error correction capability of the error correction circuit 154 occurs, the error location detector 220 generates an error location bit CORR<#> of a logic low level corresponding to the read bit RDATA<#>, and accordingly, an inverted error location bit CORRB<#> may be output at a logic high level.

Referring to FIG. 9C, the error correction part 230_# may output the read bit RDATA<#> of a logic high level as an error-corrected bit CDATA<#> as it is according to the error location bit CORR<#> of a logic low level. The detection part 170_# may output a miscorrection detection bit MIS_CORR<#> of a logic low level according to the read bit RDATA<#> of a logic high level or the inverted error location bit CORRB<#> of a logic high level. The masking part 182_# may output the error-corrected bit CDATA<#> of a logic high level as a test bit TDATA<#> according to the miscorrection detection bit MIS_CORR<#>of a logic low level.

Next, in the fourth error case, a read bit RDATA<#> becomes a logic low level, since the read bit RDATA<#> is not an error bit but a normal read bit. When a miscorrection occurs, the read bit RDATA<#>is at a logic low level, but the error location detector 220 performs a malfunction to generate an error location bit CORR<#> to a logic high level corresponding to the normal read bit RDATA<#>. Accordingly, an inverted error location bit CORRB<#> may be output at a logic low level.

Referring to FIG. 9D, the error correction part 230_# may invert the read bit RDATA<#> according to the error location bit CORR<#> of a logic high level to output an error-corrected bit CDATA<#> of a logic high level. The detection part 170_# may output a miscorrection detection bit MIS_CORR<#> of a logic high level according to the read bit RDATA<#> of a logic low level and the inverted error location bit CORRB<#> of a logic low level. The masking part 182_# may mask the error-corrected bit CDATA<#> according to the miscorrection detection bit MIS_CORR<#> of a logic high level to output a test bit TDATA<#> at a logic low level.

Thereafter, the compression circuit 184 may compress the 128-bit test data TDATA<127:0> to output a test result signal TOUT. As described in the first error case of FIG. 9A, if no error has occurred in the 128-bit read data RDATA<127:0>, the compression circuit 184 may output a test result signal TOUT indicating that the test result has passed to the test input/output line TGIO, accordingly, as all test bits have a logic low level. Further, as described in the second error case of FIG. 9B, if an error has occurred in one read bit RDATA<#> of the 128-bit read data RDATA<127:0> but the error has been corrected, the compression circuit 184 may output a test result signal TOUT indicating that the test result has passed to the test input/output line TGIO, accordingly, as all test bits have a logic low level.

On the other hand, as described in the third error case of FIG. 9C, if a multi-bit error occurs in the 128-bit read data RDATA<127:0> and all error bits are not corrected, the compression circuit 184 may output a test result signal TOUT indicating that the test result has failed to the test input/output line TGIO, accordingly, as a test bit corresponding to an uncorrected error bit has a logic high level. Further, as described in the third error case of FIG. 9D, if a multi-bit error occurs in the 128-bit read data RDATA<127:0> and a miscorrection is performed on a normal read bit, the compression circuit 184 may output a test result signal TOUT indicating that the test result has passed to the test input/output line TGIO. In this case, when a predetermined number of cell blocks among all cell blocks are grouped and tested, the miscorrection occurs but an actual error does not occur, the masking circuit 182 may output all grouped test bits at a logic low level, and the compression circuit 184 may output a test result signal TOUT indicating that the test result of the grouped cell blocks is a pass to the test input/output line TGIO. That is, in an embodiment of the present disclosure, when an error correction operation has been performed while the read data does not contain an error bit, due to the miscorrection of the on-chip ECC circuit in the test mode, the test result may be forcibly set as a pass and notified to an external device. Accordingly, an unnecessary repair operation can be prevented by preventing an incorrect failure determination, thereby increasing yield.

In the above embodiment, the miscorrection detection circuit 170 and the masking circuit 182 have been described as having NOR gates, but the embodiments of the present disclosure are not limited thereto. For example, the miscorrection detection circuit 170 and the masking circuit 182 may be formed of NAND gates, and in this case, the polarities (phases) of input/output signals may be changed.

Hereinafter, a parallel test operation of the memory device 100 according to an embodiment of the present disclosure will be described with reference to FIGS. 1 to 10.

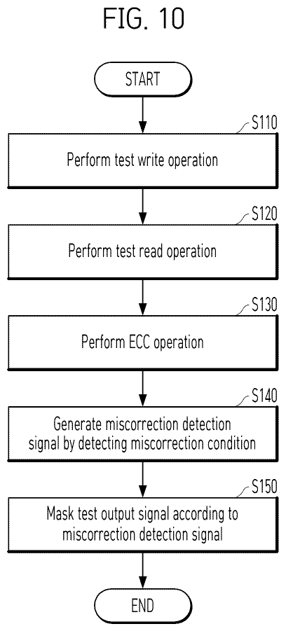

FIG. 10 is a flowchart for describing a test operation of the memory device 100 according to an embodiment of the present disclosure.

Referring to FIG. 10, when a write command is input in a test mode, a test write operation may be performed at operation S110. During the test write operation, the data input circuit 162 may buffer external data DIO input to a global input/output line GIO and receive the buffered data as write data WDATA. The parity generation circuit 152 may calculate write parity bits WPTY using the write data WDATA transmitted from the data input circuit 162. The normal write circuit 142 and the parity write circuit 144 may write the 128-bit write data WDATA and the 8-bit write parity bits WPTY into cell blocks MB0 to MB15 and MBECC, respectively. In this case, the write data WDATA provided in the test mode may have a specific target test pattern. For example, the write data WDATA may be composed of all-zero bits.

According to an embodiment, the normal write circuit 142 and the parity write circuit 144 may set the write data WDATA and the write parity bits WPTY as a target test pattern (e.g., all-zero bits) and write them to the normal cell region 112 and the parity cell region 114, respectively.

Next, when a read command is inputted, a test read operation may be performed at operation S120. During the test read operation, the normal read circuit 132 and the parity read circuit 134 may read 128-bit read data RDATA and 8-bit read parity bits RPTY from the cell blocks MB0 to MB15 and MBECC.

Thereafter, the error correction circuit 154 may perform an error correction operation at operation S130. The error correction circuit 154 may output error-corrected data CDATA by performing an error correction operation on the read data RDATA using the read parity bits RPTY. The error correction circuit 154 may perform an error correction operation of inverting an error bit among the read bits of the read data RDATA.

The miscorrection detection circuit 170 may detect a miscorrection condition in the test mode to generate a miscorrection detection signal MIS_CORR at operation S140. The miscorrection detection circuit 170 may generate the miscorrection detection signal MIS_CORR by detecting a case in which the read data RDATA does not contain an error bit but an error correction operation has been performed on the read data RDATA, in the test mode.

The test output circuit 180 may mask a test result signal TOUT according to the miscorrection detection signal MIS_CORR at operation S150. The test output circuit 180 generates the test result signal TOUT corresponding to the error-corrected data CDATA, while selectively masking the test result signal TOUT according to the miscorrection detection signal MIS_CORR. The test output circuit 180 may output the test result signal TOUT indicating a pass/fail to a test input/output line TGIO.

While the present invention has been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A memory device comprising:
a normal cell region and a parity cell region;
an error correction circuit configured to perform an error correction operation on read data output from the normal cell region based on read parity bits output from the parity cell region to generate error-corrected data;
a miscorrection detection circuit configured to detect whether the error correction operation is performed on the read data not containing an error bit to generate a miscorrection detection signal; and
a test output circuit configured to generate, in a test mode, a test result signal corresponding to the error-corrected data while masking the test result signal according to the miscorrection detection signal.

2. The memory device of claim 1,
wherein the error correction circuit is configured to generate an error location signal indicating a location of an error bit of the read data based on the read parity bits, and perform the error correction operation on the read data according to the error location signal,
wherein the miscorrection detection circuit is configured to determine whether the error correction operation is performed on the read data based on the error location signal.

3. The memory device of claim 2, wherein, when error bits of the read data, which are beyond an error correction capability, occur, the error correction circuit is configured to generate the error location signal for normal bits of the read data except for the error bits of the read data.

4. The memory device of claim 2, wherein the error correction circuit includes:
a code operator configured to generate preliminary parity bits based on the read data;
an error location detector configured to compare the preliminary read parity bits with the read parity bits to generate the error location signal; and
an error corrector configured to perform the error correction operation on the read data according to the error location signal.

5. The memory device of claim 2,
wherein the miscorrection detection circuit includes a plurality of detection logics corresponding to read bits of the read data, respectively,
wherein each of the plurality of detection logics is configured to output a corresponding bit of the miscorrection detection signal to a first bit when a corresponding read bit of the read bits is a target bit and a corresponding bit of the error location signal is the first bit.

6. The memory device of claim 1, wherein the test output circuit includes:
a masking circuit configured to selectively mask, in the test mode, the error-corrected data according to the miscorrection detection signal to generate test data; and
a compression circuit configured to compress the test data to output the test result signal.

7. The memory device of claim 6,
wherein the masking circuit includes a plurality of masking logics corresponding to error-corrected bits of the error-corrected data, respectively,
wherein, when a test mode signal is activated, each of the plurality of masking logics is configured to selectively mask the corresponding error-corrected bit according to a corresponding bit of the miscorrection detection signal to output a corresponding bit of the test data.

8. The memory device of claim 7, wherein each of the plurality of masking logics is configured to set the corresponding bit of the test data to a target bit when the corresponding bit of the miscorrection detection signal is at a first logic level, regardless of a logic level of the corresponding error-corrected bit.

9. The memory device of claim 6, wherein the compression circuit is configured to output the test result signal indicating that a test result is a pass when all bits of the test data are a target bit.

10. The memory device of claim 1, further comprising:
a parity generation circuit configured to generate write parity bits based on write data; and
a write circuit configured to write the write data and the write parity bits to the normal cell region and the parity cell region, respectively.

11. The memory device of claim 10, wherein, in the test mode, the write circuit is configured to:
externally receive the write data and the write parity bits having a target test pattern, or
set the write data and the write parity bits to the target test pattern.

12. A memory device comprising:
an error correction circuit configured to generate an error location signal indicating a location of an error bit of read data based on read parity bits, and perform an error correction operation on the read data according to the error location signal to generate error-corrected data;
a miscorrection detection circuit configured to detect whether the error correction operation is performed on the read data not containing an error bit, according to the read data and the error location signal to generate a miscorrection detection signal; and
a test output circuit configured to generate, in a test mode, a test result signal corresponding to the error-corrected data while masking the test result signal according to the miscorrection detection signal.

13. The memory device of claim 12, wherein, when error bits of the read data, which are beyond an error correction capability, occur, the error correction circuit is configured to generate the error location signal for normal bits of the read data except for the error bits of the read data.

14. The memory device of claim 12, further comprising:
a parity generation circuit configured to generate write parity bits based on write data;
a write circuit configured to write the write data and the write parity bits to a normal cell region and a parity cell region, respectively; and
a read circuit configured to read the read parity bits and the read data from the parity cell region and the normal cell region, respectively.

15. A test method of a memory device, the test method comprising:
generating an error location signal indicating a location of an error bit of read data based on read parity bits;
performing an error correction operation on the read data according to the error location signal to generate error-corrected data;
detecting whether the error correction operation is performed on the read data not containing an error bit, according to the read data and the error location signal to generate a miscorrection detection signal; and
generating a test result signal corresponding to the error-corrected data while masking the test result signal according to the miscorrection detection signal.

16. The test method of claim 15, wherein the generating the error location signal includes:
generating, when error bits of the read data, which are beyond an error correction capability, occur, the error location signal for normal bits of the read data except for the error bits.

17. The test method of claim 15, wherein detecting whether the error correction operation is performed on the read data not containing the error bit includes:
determining whether the read data contains the error bit by checking whether the read data is a target test pattern; and
determining whether the error correction operation has been performed according to the error location signal.

18. The test method of claim 15, wherein generating the test result signal includes:
selectively masking the error-corrected data according to the miscorrection detection signal to generate test data; and
compressing the test data to output the test result signal.

19. The test method of claim 18,
wherein bits of the miscorrection detection signal, bits of the error-corrected data, and bits of the test data correspond one-to-one, and
wherein selectively masking the error-corrected data includes:
setting a corresponding bit of the test data to a target bit when a corresponding bit of the miscorrection detection signal is at a first logic level, regardless of a logic level of a corresponding bit of the error-corrected data.

20. The test method of claim 15, further comprising:
generating write parity bits based on write data;
writing the write data and the write parity bits to a normal cell region and a parity cell region, respectively; and
reading out the read parity bits and the read data from the parity cell region and the normal cell region, respectively.

21. The test method of claim 20, wherein writing the write data and the write parity bits includes setting the write data and the write parity bits to a target test pattern.
